(19) United States
(12) Patent Application Publication
(10) Pub. No.: US 2010/0073166 A1
(43) Pub. Date: Mar. 25, 2010

(54) LASER ABLATION TO CREATE POCKET FOR DIE PLACEMENT

(76) Inventors: Roger S. Kerr, Brockport, NY (US); Timothy J. Tredwell, Fairport, NY (US); Seung-Ho Baek, Pittsford, NY (US)

Correspondence Address: EASTMAN KODAK COMPANY;PATENT LEGAL STAFF, 343 STATE STREET, ROCHESTER, NY, 14650-2201, US

(21) Appl. No.: 12/237,030

(22) Filed: Sep. 24, 2008

(51) Int. Cl. G08B 13/14; H01L 21/00

(52) U.S. Cl. 340/572.1; 438/107

(57) ABSTRACT

Exemplary embodiments provide methods and systems for assembling electronic devices, such as integrated circuit (IC) chips, by selectively and scalably embedding or seating IC elements onto/into a receiving substrate, such as a chip substrate. Specifically, the assembly of IC chips can include forming a pocket in the receiving substrate to accommodate the IC elements therein. Such pockets can be formed in the receiving substrate using laser ablation.

### DESCRIPTION OF THE INVENTION

1. Field of the Invention

This invention relates generally to assembly of semiconductor devices and, more particularly, to the assembly of integrated circuit elements.

2. Background of the Invention

As market demand increases for integrated circuit (IC) products such as radio frequency identification (RFID) tags, and as IC die sizes shrink, high assembly throughput rates for very small die and low production costs are crucial in providing commercially-viable products. For example, the cost of an RFID device still depends on assembly complexity.

Conventional methods for assembling IC products include pick and place techniques. Such techniques involve a manipulator, such as a robot arm, to remove IC dies from a wafer and place them into a die carrier. The dies are subsequently mounted onto a substrate with other electronic components, such as antennas, capacitors, resistors, and inductors to form an electronic device. However, these techniques have drawbacks and disadvantages. For example, the pick and place techniques involve complex robotic components and control systems that handle only one die at a time. In addition, pick and place techniques have limited placement accuracy, and have a minimum die size requirement.

Thus, there is a need to overcome these and other problems of the prior art and to provide controllable methods for a scalable and low cost assembly in transferring and assembling electronic device elements with chip substrates.

### SUMMARY OF THE INVENTION

In accordance with the present teachings, a method for assembling integrated circuits is provided.

The exemplary method can include providing a chip substrate; applying a laser source to a surface of the chip substrate for selectively ablating one or more portions of the chip substrate; positioning one or more IC elements that are attached to a release layer with respect to the chip substrate such that each IC element contacts a corresponding ablated portion of the chip substrate; and embedding each IC element into the corresponding ablated portion of the chip substrate.

In accordance with the present teachings, a method for assembling integrated circuits is provided.

The exemplary method can include selectively ablating a chip substrate to form one or more pockets in the chip substrate; positioning one or more IC elements that are attached to a release layer with respect to the chip substrate such that each IC element contacts a corresponding pocket of the chip substrate; and embedding each IC element into the corresponding pocket of the chip substrate.

In accordance with the present teachings, an integrated circuit assembly is provided.

The exemplary assembly can include a chip substrate selectively ablated at one or more portions thereof by a laser ablation; one or more released IC elements embedded in a bump side up orientation into the corresponding ablated portion of the chip substrate; and supporting electronics printed on the chip substrate, wherein the supporting electronics electrically contact each exposed IC element.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 depicts an exemplary method for forming pockets in a substrate in accordance with the present teachings.

FIGS. 2A-2D depict an exemplary process at various stages for assembling IC elements according to the method depicted in FIG. 1 in accordance with the present teachings.

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” The term “at least one of” is used to mean one or more of the listed items can be selected.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

Exemplary embodiments provide methods and systems for assembling electronic devices, such as integrated circuit (IC) chips. For example, IC elements/components can be selectively and scalably transferred and assembled (e.g., embedded) within a receiving material such as an intermediate substrate or a final chip substrate to form IC chips. As disclosed herein, exemplary IC elements can include, but are not limited to, display elements, detector elements, processor elements, or any other IC elements as would be understood by one of ordinary skill in the art.

For ease of illustration, the invention will be described with reference to an assembly of IC chips in an exemplary form of radio frequency identification (RFID) chips. RFID chips can be used in various applications, such as inventory control, airport baggage monitoring, as well as security and surveillance applications for location monitoring and real time tracking of such items. Generally, an RFID chip can include, e.g., a plurality of die elements (dies) mounted onto related supporting electronics that can be located on a chip substrate. The plurality of dies can be an integrated circuit that performs RFID operations known to one of ordinary skill in the art, such as communicating with one or more chip readers according to various interrogation protocols of RFID. Each die can further include conductive connections to electrically contact with the chip supporting electronics. The conductive connections of each die can include, for example, conductive traces, such as conductive ink traces, or conductive bumps or bumps attached to a strap.

Even further, it will be appreciated the placement of die on a surface can be such that the die are magnetically aligned prior to subsequent processing. An example of the magnetic alignment of the die is disclosed in, for example commonly owned published application number 2006-0131504, and incorporated herein by reference in its entirety.

When assembling RFID chips, the die can be mounted, for example, in either a “bump side up” or “bump side down” orientation As used herein, the terms “bump side up” and “bump side down” denote alternative implementations of the plurality of dies. In particular, these terms designate the orientation of connection bumps in relation to a subsequent surface to be transferred and assembled. That is, in a “bump side up” orientation, the plurality of dies can be transferred to the subsequent surface with bumps facing away from the subsequent surface. In a “bump side down” orientation, the plurality of dies can be transferred to the subsequent surface with bumps facing towards, and in contact with the subsequent surface. In various embodiments, the subsequent surface can be a receiving surface that includes, for example, an intermediate transfer surface, or an actual final chip substrate to which the dies can be permanently attached. In various embodiments, the subsequent surface can be rigid or flexible and can be formed of a material chosen from, for example, plastic, silicon wafer, etc., for either the intermediate transfer substrate or a final chip substrate.

As disclosed herein, the assembly of IC elements (e.g., the dies for RFID chips) can include releasing the IC elements from a release layer, transferring them onto a receiving surface (e.g., a chip substrate surface) and accommodating (e.g., embedding) them within the receiving surface. In addition, the embedded IC elements can be locally encapsulated.

The “release layer” can be in a form of, for example, a web, a film, a plate, a roll, and their various combinations, to which the IC elements can be attached. The release layer can be a rigid release layer or a flexible release layer. As used herein, the term “flexible” refers to the ability of a material, structure, device or device component to be deformed into a curved shape without undergoing a transformation that introduces significant strain, such as strain characterizing the failure point of a material, structure, device, or device component. The release layer can therefore include, but is not limited to, a flexible web, flexible film, flexible plate, flexible roll (including roll-to-roll), and their various combinations. In addition, the term “release layer” can provide a large releasing area, for example, such as a 2 square-meter releasing area and as much as an entire surface of a web or roll. Accordingly, a large area for transferring and receiving onto/into the chip substrate can be selectively performed.

In various embodiments, the IC elements can be attached to the release layer through a functional surface formed on a release support. The functional surface can be adhesive to initially hold the attached IC elements in place and can further provide an easy release when necessary. For example, the functional surface can include a phase-change surface or an adhesive surface formed on the release support. In one example, the release layer can include a phase-change surface that provides an adhesive surface when the IC elements contact therewith and further provides a phase-change when exposed to an energy source such as a laser. This phase change can be used to release the attached IC elements from the release layer and transfer the IC elements onto a receiving surface such as a chip substrate surface. In another example, the release layer can be a sticky tape such as a green tape or a blue tape known in industry or can include an epoxy, glue, or wax applied on a release support to provide surface adhesiveness and further to provide easy removal of the attached IC elements.

The chip substrate can be rigid or flexible and can include a material including, for example, a plastic. A flexible substrate can include a roll-to-roll substrate. The term “plastic” refers to any synthetic or naturally occurring material or combination of materials that can be molded or shaped, generally when heated and hardened into a desired shape. Exemplary plastics useful in assembling IC chips can include, but are not limited to, polymers, resins and/or cellulose derivatives. In an additional example, the plastics useful in assembling IC chips can include polyester, polystyrene, ABS, acrylic, polycarbonate and PVC. The term “plastic” is further intended to include composite plastic materials including one or more plastics with one or more additives, such as structural enhancers, fillers, fibers, plasticizers, stabilizers, and/or additives which may provide desired chemical or physical properties. Other suitable materials can be used for the chip substrate including, but not limited to metal, glass, and coated metal.

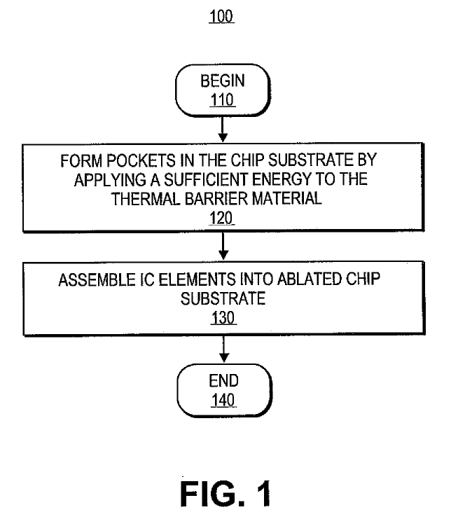

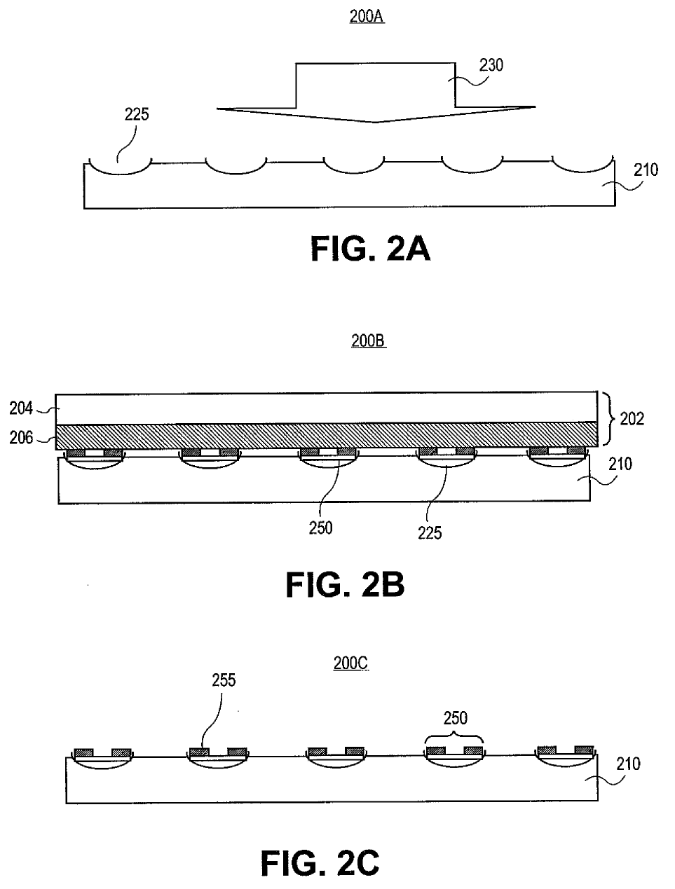

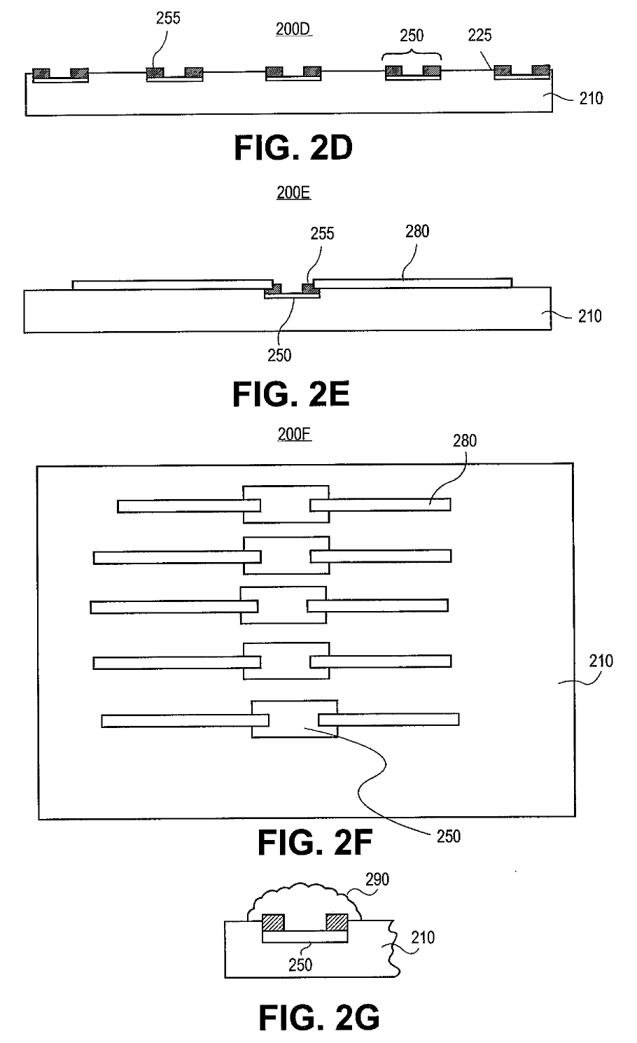

In various embodiments, the assembly of IC chips can include, for example, ablating the receiving surface to accommodate the IC elements into the receiving material (see FIGS. 1-2). For example, the ablating of the chip substrate can be performed by using a laser to form a pocket in the chip substrate.

FIG. 1 and FIGS. 2A-2D depict exemplary methods and systems for assembling IC elements in a chip substrate using various laser ablation techniques for a “bump side up” assembly in accordance with the present teachings. Specifically, FIG. 1 depicts an exemplary method 100 for transferring IC elements into a chip substrate in accordance with the present teachings.

FIG. 1 and FIGS. 2A-2D depict an exemplary method and process for assembling IC chips using an energy source to selectively ablate a chip substrate in accordance with the present teachings.

As used herein, the term “energy source” refers to a sufficient energy, such as an optical, electrical, magnetic, radiative energy or various energy combinations thereof using various energy sources for ablating the substrate. The energy source can ablate the underlying exemplary plastic chip substrate. Depending on the power and exposing time of the energy applied, various portions of the plastic chip substrate can be ablated to a predetermined depth. Other components, such as IC elements, can be pushed or placed in and assembled (e.g., embedded or seated) in the exemplary plastic chip substrate subsequent to the laser ablation.

Specifically, FIG. 1 depicts an exemplary method 100 for forming pockets in a substrate by using a laser source in accordance with the present teachings. In addition, FIGS. 2A-2D depict an exemplary process at various stages for assembling IC elements according to the method 100 depicted in FIG. 1 in accordance with the present teachings. Although the method 100 will be described with reference to FIGS. 2A-2D for illustrative purposes, the process of method 100 is not limited to the structures shown in FIGS. 2A-2D.

As used herein, the term “pocket” refers to a concave area, relief, or depression formed on a surface of a substrate by, for example, removing a portion of the substrate material. The pocket can be curved or non-curved and can have a regular shape or an irregular shape. For example, the pocket can have various regular cross sectional shapes, such as, for example, rectangular, polygonal, oval, or circular shape. Although the term “pocket” is referred to throughout the description herein for illustrative purposes, it is intended that the term also encompass other concave area in the substrate including, but not limited to, bracket, cell, opening, hole, cave, recess, trench and their various combinations.

The method 100 in FIG. 1 begins at 110. At 120, the selectively directed laser source can be applied at an energy that is sufficient for ablating portions of the chip substrate as desired. In one embodiment, one or more portions of chip substrate can be ablated to form pockets inside the chip substrate. The selectively directed laser source can yield a desired pattern or array of pockets on the chip substrate depending on the particular applications of the chip substrate. For example, as shown in FIG. 2A, the device 200A includes a pattern of pockets 220 formed on the chip substrate 210.

The method in FIG. 1 continues with placing IC elements into the formed pockets as shown in FIG. 2B. The method 100 in FIG. 1 can conclude at 140.

In FIG. 2A, for example, a laser source used as an optical energy 230 can be used to selectively ablate the underlying portions of the chip substrate 210. The optical energy 230 can be a UV laser or an IR laser with sufficient power and exposure time to ablate portions of the chip substrate 210 forming one or more pockets 225 inside the chip substrate 210. For example, depending upon a power of the laser, it is expected that the plastic chip substrate can deform to a depth of about 1 micron.

In FIG. 2B, one or more IC elements 250 that are attached to a release layer 202 can be positioned closely adjacent to the chip substrate 210 such that each IC element 250 seats in a corresponding ablated portion 225 of the chip substrate 210. In various embodiments, a suitable compressive pressure can be applied onto release layer 202 to facilitate the placement of the IC elements into the pockets 225 of the chip substrate 210. In various embodiments, other means, such as heating means, can also be used to facilitate placement of the IC elements 250 into the chip substrate 210.

In FIG. 2C, the release layer 202 can be easily removed by, for example, detaching a tape-adhesive or inducing phase change of a functional layer 206. The IC elements 250 that are assembled in the chip substrate 210 by seating in corresponding pockets 225 can then be exposed as shown in FIG. 2C. Likewise, supporting electronics can be printed on the exposed IC elements 250 of the device 200C.

In FIG. 2D, an optional encapsulation of the embedded RFID dies 250 is depicted. Encapsulation can be performed at any stage after embedding of the RFID dies, and can be local to individually encapsulate only the RFID dies. Application of the encapsulation material 290 can be by printing in a manner similar to that described in connection with applying the solvent softening agent. The encapsulating material can be a curable clear or opaque material including, but not limited to, polyurethane, polyethylene, polypropylene, polystyrene, polyester, and epoxy, and combinations thereof.

It is noted that the disclosed methods and processes shown in FIGS. 1-2 can be “controllable” for selectively releasing, transferring, and/or assembling IC elements. For example, by controlling the softened area of the chip substrate, one or more selected IC elements or multiple IC elements can be assembled at the same time. In addition, the geometry and distribution of the released IC elements can be spatially controlled during the assembly.

It is also noted that the disclosed methods and processes shown in FIGS. 1-2 can be “controllable” for selectively screening (inspecting), and/or repairing during the assembling of the IC elements. For example, a group of the one or more IC elements that are attached to a release layer can be selected for an inspection using a suitable test circuitry. The inspected IC element that needs to be repaired can then be determined and selectively released from the release layer and selectively transferred and assembled to the chip substrate using the disclosed methods and processes for a subsequent individual or group repair.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for assembling integrated circuits comprising:
providing a chip substrate;
applying a laser source to a surface of the chip substrate for selectively ablating one or more portions of the chip substrate;
positioning one or more IC elements that are attached to a release layer with respect to the chip substrate such that each IC element contacts a corresponding ablated portion of the chip substrate; and
embedding each IC element into the corresponding ablated portion of the chip substrate.

2. The method of claim 1, wherein applying the laser source is for a predetermined time and temperature to achieve a pocket sized to receive the IC chip.

3. The method of claim 1, wherein the chip substrate comprises plastic.

4. The method of claim 1, further comprising providing a conductive adhesive between the one or more IC elements and a pocket of the chip substrate.

5. The method of claim 1, further comprising applying one or more of a pressure and a heat to embed each IC element into the corresponding ablated chip substrate.

6. The method of claim 1, further comprising exposing each embedded IC element by removing the release layer.

7. The method of claim 1, further comprising printing supporting electronics onto the chip substrate, wherein the supporting electronics electrically contact each exposed IC element.

8. The method of claim 1, wherein the element is embedded flush with or below a surface of the chip substrate.

9. The method of claim 1, further comprising locally encapsulating each of he embedded IC elements.

10. The method of claim 1, wherein the chip substrate comprises a roll-to-roll material.

11. The method of claim 1, wherein the release layer comprises a roll-to-roll material.

12. The method of claim 1, wherein the substrate comprises plastic.

13. A method for assembling integrated circuits comprising:
selectively ablating a chip substrate to form one or more pockets in the chip substrate;
positioning one or more IC elements that are attached to a release layer with respect to the chip substrate such that each IC element contacts a corresponding pocket of the chip substrate; and
embedding each IC element into the corresponding pocket of the chip substrate.

14. The method of claim 13, wherein selectively ablating comprising applying a laser source to a surface of the substrate.

15. The method of claim 14 wherein the laser source comprises one or more of optical, electrical, magnetic, or radiative energy.

16. The method of claim 14, further comprising applying one or more of pressure and heat to embed each IC element into the chip substrate.

17. The method of claim 13, wherein the element is embedded flush with a surface of the chip substrate.

18. The method of claim 13, wherein the element is embedded below a surface of the chip substrate.

19. The method of claim 13, further comprising printing supporting electronics onto the chip substrate prior to transferring the one or more IC elements.

20. An integrated circuit assembly comprising:
a chip substrate selectively ablated at one or more portions thereof by a laser ablation;
one or more released IC elements embedded in a bump side up orientation into the corresponding ablated portion of the chip substrate; and
supporting electronics printed on the chip substrate, wherein the supporting electronics electrically contact each exposed IC element.
